(19) United States
(12) Patent Application Publication
(10) Pub. No.: US 2023/0157068 A1
(43) Pub. Date: May 18, 2023

(54) ARRAY SUBSTRATE AND MANUFACTURING METHOD THEREOF

(71) Applicant: Wuhan China Star Optoelectronics Semiconductor Display Technology Co., Ltd., Wuhan, Hubei (CN)

(72) Inventor: Weibin ZHANG, Wuhan, Hubei (CN)

(73) Assignee: Wuhan China Star Optoelectronics Semiconductor Display Technology Co., Ltd., Wuhan, Hubei (CN)

(21) Appl. No.: 16/970,728

(22) PCT Filed: Jun. 24, 2020
(86) PCT No.: PCT/CN2020/097896

§ 371 Date: Aug. 18, 2020

(30) Foreign Application Priority Data
May 19, 2020 (CN) 202010425170.X

(51) Int. Cl. H10K 59/12; H01L 29/417; H01L 29/786; H01L 29/66

(52) U.S. Cl. CPC H10K 59/1201; H01L 29/41733; H01L 29/78696; H01L 29/6675

(57) ABSTRACT

An array substrate and a manufacturing method thereof are provided. The array substrate includes an active layer and a source/drain electrode layer. Wherein, the active layer is patterned to form a channel area, the source/drain electrode layer includes a first source/drain electrode layer and a second source/drain electrode layer disposed in a stack, areas where the first source/drain electrode layer is in contact with the active layer form doped areas, a material of the first source/drain electrode layer is same as a material of the active layer, both of which are semiconductor materials, while ion doping concentrations of the first source/drain electrode layer and the active layer are different.

### FIELD OF INVENTION

The present disclosure relates to the field of display technologies, and more particularly, to an array substrate and a manufacturing method thereof.

### BACKGROUND OF INVENTION

In manufacturing processes of conventional active-matrix organic light-emitting diode (AMOLED) devices, complementary metal oxide semiconductor (CMOS) devices are usually used to compose basic units of panels' driver circuits. In general, B-type ions or P-type ions are doped into an active layer to form a channel area of the active layer. An amorphous silicon thin film is usually prepared first, and is annealed to form a polysilicon layer; a gate insulating layer and a gate electrode are then disposed on the polysilicon layer, and then gases are injected into the polysilicon layer and activated at a high temperature to generate active ions to react with the polysilicon layer. This causes two high temperature activation reactions and increases a risk of breaking the gate electrode, and meanwhile, adding ion implantation processes also increases costs.

Therefore, current technology has problems of increased manufacturing processes and higher lighting costs existing in AMOLED devices.

Technical problem: an embodiment of the present disclosure provides an array substrate and a manufacturing method thereof to effectively solve the problems of increased manufacturing processes and higher lighting costs existing in AMOLED devices.

### SUMMARY OF INVENTION

In a first aspect, an embodiment of the present disclosure provides an array substrate. The array substrate includes:

a substrate base;

a buffer layer disposed on the substrate base;

a gate electrode metal layer disposed on one side of the buffer layer away from the substrate base;

a gate insulating layer disposed on one side of the gate electrode metal layer away from the buffer layer;

an active layer disposed on one side of the gate insulating layer away from the gate electrode metal layer and patterned to form a channel area;

an interlayer dielectric layer disposed on one side of the interlayer dielectric layer away from the gate insulating layer; and

a source/drain electrode layer disposed on one side of the active layer away from the gate insulating layer and patterned to form a source electrode and a drain electrode;

wherein the source/drain electrode layer includes a first source/drain electrode layer and a second source/drain electrode layer, areas where the first source/drain electrode layer is in contact with the active layer form doped areas, the second source/drain electrode layer is disposed on one side of the first source/drain electrode layer away from the substrate base, a material of the first source/drain electrode layer is same as a material of the active layer, while ion doping concentrations of the first source/drain electrode layer and the active layer are different.

In the array substrate provided by the present disclosure, the interlayer dielectric layer is provided with through-holes penetrating through the interlayer dielectric layer and forming flat areas on the gate insulating layer, the first source/drain electrode layer is paved over the through-holes, and the first source/drain electrode layer in the flat areas is connected to the channel area to form the doped areas.

In the array substrate provided by the present disclosure, a shape of the through-holes comprises an inverted trapezoid.

In the array substrate provided by the present disclosure, a thickness of the active layer is same as a thickness of the first source/drain electrode layer.

In the array substrate provided by the present disclosure, a contact area of the second source/drain electrode layer and the first source/drain electrode layer is greater than an orthographic projection area of the second source/drain electrode layer on the substrate base. Photoresists also include organic resins.

In a second aspect, an embodiment of the present disclosure further provides a manufacturing method of an array substrate, which is used to manufacture the above array substrate. The method includes following steps:

providing a substrate;

disposing the substrate base, the buffer layer, a gate electrode, and the gate insulating layer on the substrate in sequence;

depositing a semiconductor layer on the gate insulating layer and processing the semiconductor layer to obtain the channel area;

depositing the interlayer dielectric layer on the first semiconductor layer and etching the interlayer dielectric layer to form the through-holes; and

depositing the first source/drain electrode layer and the second source/drain electrode layer in the through-holes and processing the first and second source/drain electrode layers to obtain the doped areas, the source electrode, and the drain electrode.

In the manufacturing method provided by the present disclosure, the step of depositing the semiconductor layer on the gate insulating layer and processing the semiconductor layer to obtain the channel area includes:

providing first doped amorphous silicon doped with a dopant material with a first doping concentration;

using the first doped amorphous silicon to form a first amorphous silicon layer as the semiconductor layer;

laser annealing the first amorphous silicon layer to obtain a polysilicon layer; and

patterning the polysilicon layer to obtain the channel area.

In the manufacturing method provided by the present disclosure, the step of providing the first doped amorphous silicon doped with the dopant material with the first doping concentration includes:

injecting methane, hydrogen, and phosphorus hydride into a reaction chamber and dissociating them under a thermal energy condition or a light energy condition to obtain the first doped amorphous silicon.

In the manufacturing method provided by the present disclosure, the step of providing the first doped amorphous silicon doped with the dopant material with the first doping concentration includes:

injecting methane, hydrogen, and boron trifluoride into a reaction chamber and dissociating them under a thermal energy condition or a light energy condition to obtain the first doped amorphous silicon.

In the manufacturing method provided by the present disclosure, the step of depositing the first source/drain electrode layer and the second source/drain electrode layer in the through-holes and processing the first and second source/drain electrode layers to obtain the doped areas, the source electrode, and the drain electrode includes:

providing second doped amorphous silicon doped with a dopant material with a second doping concentration;

using the second doped amorphous silicon to form a second amorphous silicon layer to be the first source/drain electrode layer;

disposing the second source/drain electrode layer on the second amorphous silicon layer; and

patterning the second doped amorphous silicon and the second source/drain electrode layer to obtain the doped areas, the source electrode, and the drain electrode.

In a third aspect, the present disclosure provides a display panel including the above array substrate. The display panel includes:

a substrate base;

a buffer layer disposed on the substrate base;

a gate electrode metal layer disposed on one side of the buffer layer away from the substrate base;

a gate insulating layer disposed on one side of the gate electrode metal layer away from the buffer layer;

an active layer disposed on one side of the gate insulating layer away from the gate electrode metal layer and patterned to form a channel area;

an interlayer dielectric layer disposed on one side of the interlayer dielectric layer away from the gate insulating layer; and

a source/drain electrode layer disposed on one side of the active layer away from the gate insulating layer and patterned to form a source electrode and a drain electrode;

wherein the source/drain electrode layer comprises a first source/drain electrode layer and a second source/drain electrode layer, areas where the first source/drain electrode layer is in contact with the active layer form doped areas, the second source/drain electrode layer is disposed on one side of the first source/drain electrode layer away from the substrate base, a material of the first source/drain electrode layer is same as a material of the active layer, while ion doping concentrations of the first source/drain electrode layer and the active layer are different.

In the display panel provided by the present disclosure, the interlayer dielectric layer is provided with through-holes penetrating through the interlayer dielectric layer and forming flat areas on the gate insulating layer, the first source/drain electrode layer is paved over the through-holes, and the first source/drain electrode layer in the flat areas is connected to the channel area to form the doped areas.

In the display panel provided by the present disclosure, a shape of the through-holes comprises an inverted trapezoid.

In the display panel provided by the present disclosure, a thickness of the active layer is same as a thickness of the first source/drain electrode layer.

In the display panel provided by the present disclosure, a contact area of the second source/drain electrode layer and the first source/drain electrode layer is greater than an orthographic projection area of the second source/drain electrode layer on the substrate base.

In a fourth aspect, the present disclosure provides a manufacturing method of a display panel, which is used to manufacture the above display panel. The method includes:

providing a substrate;

disposing the substrate base, the buffer layer, a gate electrode, and the gate insulating layer on the substrate in sequence;

depositing a semiconductor layer on the gate insulating layer and processing the semiconductor layer to obtain the channel area;

depositing the interlayer dielectric layer on the first semiconductor layer and etching the interlayer dielectric layer to form the through-holes; and

depositing the first source/drain electrode layer and the second source/drain electrode layer in the through-holes and processing the first and second source/drain electrode layers to obtain the doped areas, the source electrode, and the drain electrode.

In the manufacturing method provided by the present disclosure, the step of depositing the semiconductor layer on the gate insulating layer and processing the semiconductor layer to obtain the channel area includes:

providing first doped amorphous silicon doped with a dopant material with a first doping concentration;

using the first doped amorphous silicon to form a first amorphous silicon layer as the semiconductor layer;

laser annealing the first amorphous silicon layer to obtain a polysilicon layer; and

patterning the polysilicon layer to obtain the channel area.

In the manufacturing method provided by the present disclosure, the step of providing the first doped amorphous silicon doped with the dopant material with the first doping concentration includes:

injecting methane, hydrogen, and phosphorus hydride into a reaction chamber and dissociating them under a thermal energy condition or a light energy condition to obtain the first doped amorphous silicon.

In the manufacturing method provided by the present disclosure, the step of providing the first doped amorphous silicon doped with the dopant material with the first doping concentration includes:

injecting methane, hydrogen, and boron trifluoride into a reaction chamber and dissociating them under a thermal energy condition or a light energy condition to obtain the first doped amorphous silicon.

In the manufacturing method provided by the present disclosure, the step of depositing the first source/drain electrode layer and the second source/drain electrode layer in the through-holes and processing the first and second source/drain electrode layers to obtain the doped areas, the source electrode, and the drain electrode includes:

providing second doped amorphous silicon doped with a dopant material with a second doping concentration;

using the second doped amorphous silicon to form a second amorphous silicon layer to be the first source/drain electrode layer;

disposing the second source/drain electrode layer on the second amorphous silicon layer; and

patterning the second doped amorphous silicon and the second source/drain electrode layer to obtain the doped areas, the source electrode, and the drain electrode.

Beneficial effect: the present disclosure provides an array substrate and a manufacturing method thereof. The array substrate includes a substrate base, a buffer layer, a gate electrode metal layer, a gate insulating layer, an active layer, an interlayer dielectric layer, and a source/drain electrode layer disposed in a stack. Wherein, the active layer is patterned to form a channel area, the source/drain electrode layer includes a first source/drain electrode layer and a second source/drain electrode layer disposed in a stack, areas where the first source/drain electrode layer is in contact with the active layer form doped areas, a material of the first source/drain electrode layer is same as a material of the active layer, both of which are semiconductor materials, while ion doping concentrations of the first source/drain electrode layer and the active layer are different. By doping ions into the semiconductor materials and forming films first and then annealing semiconductor layers to form the active layer's channel area and the first source/drain electrode layer, the present disclosure saves one ion doping step and one semiconductor annealing step, and meanwhile, the first source/drain electrode layer forms the doped areas of the active layer directly, which increases a contact area of the source/drain electrode layer and the active layer, thereby reducing a resistance of the source/drain electrode layer.

### DESCRIPTION OF DRAWINGS

FIG. 1 is a schematic cross-sectional structural diagram of an array substrate in current technology.

FIG. 2 is a schematic cross-sectional structural diagram of an array substrate according to an embodiment of the present disclosure.

FIG. 3 is a first flowchart of a manufacturing method of an array substrate according to an embodiment of the present disclosure.

FIG. 4 is a second flowchart of the manufacturing method of the array substrate according to an embodiment of the present disclosure.

FIGS. 5 to 9 are schematic structural diagrams of a manufacturing method of an array substrate according to an embodiment of the present disclosure.

### DETAILED DESCRIPTION OF PREFERRED EMBODIMENTS

The technical solutions in the embodiments of the present disclosure will be clearly and completely described below with reference to the drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative efforts are within the scope of the present disclosure.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, “counter-clockwise”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or implicitly indicating the number of technical features indicated. Thus, features limited by “first” and “second” are intended to indicate or imply including one or more than one these features. In the description of the present disclosure, “a plurality of” relates to two or more than two, unless otherwise specified.

In the description of the present disclosure, it should be noted that unless there are express rules and limitations, the terms such as “mount,” “connect,” and “bond” should be comprehended in broad sense. For example, it can mean a permanent connection, a detachable connection, or an integrate connection; it can mean a mechanical connection, an electrical connection, or can communicate with each other; it can mean a direct connection, an indirect connection by an intermediate, or an inner communication or an inter-reaction between two elements. A person skilled in the art should understand the specific meanings in the present disclosure according to specific situations.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature.

The following description provides many different embodiments or examples for implementing different structures of the present disclosure. In order to simplify the present disclosure, the components and settings of a specific example are described below. Of course, they are merely examples and are not intended to limit the present disclosure. In addition, the present disclosure may repeat reference numerals and/or reference letters in different examples, which are for the purpose of simplicity and clarity, and do not indicate the relationship between the various embodiments and/or arrangements discussed. In addition, the present disclosure provides examples of various specific processes and materials, but one of ordinary skill in the art will recognize the use of other processes and/or the use of other materials.

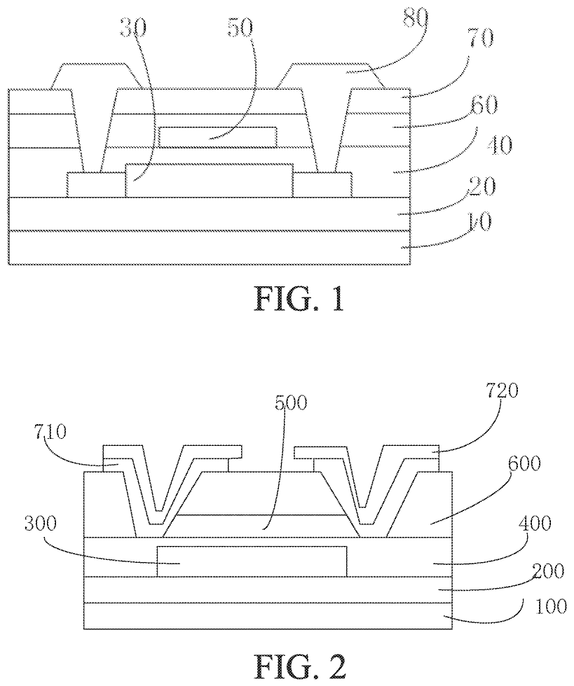

Specifically, referring to FIGS. 1 to 9, an embodiment of the present disclosure provides an array substrate which includes a substrate base, a buffer layer, a gate electrode metal layer, a gate insulating layer, an active layer, a planarization layer, and a source/drain electrode layer disposed in a stack. Wherein, the active layer is patterned to form a channel area and doped areas, the source/drain electrode layer includes a first source/drain electrode layer and a second source/drain electrode layer disposed in a stack, areas where the first source/drain electrode layer is in contact with the active layer form the doped areas, a material of the first source/drain electrode layer is same as a material of the active layer, both of which are semiconductor materials, while ion doping concentrations of the first source/drain electrode layer and the active layer are different. By doping ions into the semiconductor materials and forming films first and then annealing semiconductor layers to form the active layer's channel area and the first source/drain electrode layer, the present disclosure conserves one ion doping step and one semiconductor annealing step, and meanwhile, the first source/drain electrode layer forms the doped areas of the active layer directly, which increases a contact area of the source/drain electrode layer and the active layer, thereby reducing a resistance of the source/drain electrode layer.

In current technology, as shown in FIG. 1, the array substrate includes: a substrate base 100; a buffer layer 200 disposed on the substrate base 100; an active layer 300 disposed on one side of the buffer layer 200 away from the gate electrode metal layer and patterned to form a channel area and doped areas; a first gate insulating layer 400 disposed on one side of the active layer 300 away from the buffer layer 200; a gate electrode metal layer 500 disposed on one side of the first gate insulating layer 400 away from the active layer 300; a second gate insulating layer 600 disposed on one side of the gate electrode metal layer 500 away from the first gate insulating layer 400; an interlayer dielectric layer 700 disposed on one side of the second gate insulating layer 600 away from the gate electrode metal layer 500, wherein the interlayer dielectric layer 700 is provided with through-holes, and the through-holes penetrate through the first gate insulating layer 400 and the second gate insulating layer 600 and are defined in the doped areas of the active layer 300; a source/drain electrode layer 800 disposed in the through-holes and forming a source electrode and a drain electrode.

In current manufacturing method of the array substrate, in order to improve ion mobility of a polysilicon layer, the doped areas of the active layer 300 need to be doped with ions. In current technology, disposing the substrate base 100 and the buffer layer 200 in sequence first, then injecting methane into a reaction chamber, and through performing a high temperature activation reaction, a monocrystalline silicon film is formed on the buffer layer 200 by depositing. Then heating the formed monocrystalline silicon film to form a polysilicon layer, and etching the polysilicon layer to form the active layer 300, the active layer 300 includes the channel area and the doped areas. Then the first gate insulating layer 400 and the gate electrode metal layer 500 are deposited on the active layer 300, and after the gate electrode metal layer 500 is etched, a cross-sectional area of a gate electrode metal 500 is less than the channel area of the active layer 300. Then making holes in the first gate insulating layer 400 to form first through-holes, the first through-holes penetrate through the first gate insulating layer 400 and are defined in the channel area of the active layer 300. Injecting a reactive gas into the reaction chamber and performing another high temperature activation reaction to generate active ions or ion groups, the active ions and ion groups are introduced to surfaces of the doped areas of the active layer 300, and then the reaction chamber is heated to allow the active ions to react with silicon bonds of the active layer, thereby forming ion doping. In some embodiments, the reactive gas is boron trifluoride or phosphine.

In current technology, in order to achieve ion doping of the active layer, two high temperature activation reactions are performed on the active layer, which increases a risk of breaking the gate electrode, and meanwhile, adding ion implantation processes also increases production cost of the array substrate.

As shown in FIG. 2, the present disclosure provides an array substrate. The array substrate includes: a substrate base 100; a buffer layer 200 disposed on the substrate base 100; a gate electrode metal layer 300 disposed on one side of the buffer layer 200 away from the substrate base 100; a gate insulating layer 400 disposed on one side of the gate electrode metal layer 300 away from the buffer layer 200; an active layer 500 disposed on one side of the gate insulating layer 400 away from the gate electrode metal layer 300 and patterned to form a channel area; an interlayer dielectric layer 600 disposed on one side of the active layer 500 away from the gate insulating layer 400; and a source/drain electrode layer disposed on one side of the active layer 500 away from the gate insulating layer 400; wherein the source/drain electrode layer includes a first source/drain electrode layer 710 and a second source/drain electrode layer 720, areas where the first source/drain electrode layer 710 is in contact with the active layer 500 form doped areas, the second source/drain electrode layer 720 is disposed on one side of the first source/drain electrode layer 710 away from the substrate base 100, a material of the first source/drain electrode layer 710 is the same as a material of the active layer 500, while ion doping concentrations of the first source/drain electrode layer 710 and the active layer 500 are different.

In some embodiments, in general, a material of the substrate base 100 is glass, a material of the buffer layer 200 includes an organic layer and an inorganic layer, the organic layer is disposed on the substrate base 100, and the inorganic layer is disposed on one side of the organic layer away from the substrate base 100. The gate electrode metal layer 300 may be manufactured by using magnetron sputtering to form a metal thin film layer on the buffer layer 200. A metal material may use molybdenum, aluminum, aluminum nickel alloy, molybdenum tungsten alloy, chrome, copper, or combinations of thin films of the above materials. Then a gate electrode 300 is formed by exposing through a mask, developing, etching, and stripping. The gate insulating layer 400 is deposited on the gate electrode metal layer 300, and a material for the gate insulating layer 400 may be SiNx or SiO₂.

A material of the active layer 500 is a polysilicon layer. An amorphous silicon layer is formed first on the gate insulating layer 400, and then the amorphous silicon layer is processed by a crystallization process to form the polysilicon layer 500. Injecting methane and reactive gases into a reaction chamber, performing high temperature activation to form active ions and ion groups, forming an amorphous silicon film doped with the ions on the gate insulating layer 400, and then the amorphous silicon film is processed by the crystallization process, which heats the amorphous silicon film to a temperature above 700 degrees, to form the polysilicon layer. The polysilicon layer is patterned by injecting an etching gas into the reaction chamber to form the channel area of the active layer 500, and both sides of the channel area form the doped areas of the active layer 500.

A material of the interlayer dielectric layer 600 is one or more of silicon oxide, silicon nitride, and phosphosilicate glass. After forming the interlayer dielectric layer 600 on the active layer 500, opening holes in the interlayer dielectric layer 600, the through-holes penetrate through the interlayer dielectric layer 600 and are defined on the gate insulating layer 400, and the through-holes are defined in the doped areas of the active layer.

In some embodiments, a shape of the through-holes is an inverted trapezoid.

The first source/drain electrode layer 710 is formed in the through-holes. A first amorphous silicon layer is formed first in the through-holes, and then the first amorphous silicon layer is processed by a crystallization process to form a polysilicon layer. Injecting methane and reactive gases into the reaction chamber, performing high temperature activation to form active ions and ion groups, forming an amorphous silicon film doped with the ions on the gate insulating layer 400, and then the amorphous silicon film is processed by the crystallization process, which heats the amorphous silicon film to a temperature above 700 degrees, to form the polysilicon layer. The polysilicon layer is patterned by injecting the etching gas into the reaction chamber to form the first source/drain electrode layer 710, and the first source/drain electrode layer 710 forms the doped areas of the active layer 500. Since the shape of the through-holes is an inverted trapezoid, a cross-sectional area of the first source/drain electrode layer 710 is greater than a projection area of the first source/drain electrode layer 710, which increases a contact area of the first source/drain electrode layer 710 and the active layer 500, thereby reducing a resistance of the first source/drain electrode layer.

In some embodiments, a shape of the first source/drain electrode layer 710 is an inverted trapezoid.

In some embodiments, the shape of the first source/drain electrode layer 710 is a V-shape.

In some embodiments, materials of the active layer 500 and the first source/drain electrode layer 710 are the same, so preparation materials of the active layer 500 and the first source/drain electrode layer 710 are the same and are methane and the reactive gases that can generate ions. However, an ion doping rate of the first source/drain electrode layer 710 is greater than which of the active layer 500, so a ratio of the reactive gas for preparing the first source/drain electrode layer 710 to a mixed gas is greater than a ratio of the reactive gas for preparing the active layer 500 to the mixed gas.

In some embodiments, the mixed gas includes methane, hydrogen, and phosphine.

In some embodiments, the mixed gas includes methane, hydrogen, and boron trifluoride.

The second source/drain electrode layer 720 is disposed on one side of the first source/drain electrode layer 710 away from the gate insulating layer 400. A material of the second source/drain electrode layer is titanium. The second source/drain electrode layer and the first source/drain electrode layer form a semiconductor-metal structure, which reduces a resistance of the source/drain electrode, thereby reducing a risk of short circuits of the array substrate.

In some embodiments, a depositing shape of the first source/drain electrode layer 710 is a narrow V-shape, the second source/drain electrode layer 720 is disposed on the side of the first source/drain electrode layer 710 away from the substrate base 100, and a depositing shape of the second source/drain electrode layer is also a V-shape.

In some embodiments, the depositing shape of the first source/drain electrode layer 710 is the V-shape, the second source/drain electrode layer 720 is disposed on the side of the first source/drain electrode layer 710 away from the substrate base 100, and the depositing shape of the second source/drain electrode layer is a strip structure.

In some embodiments, the depositing shape of the first source/drain electrode layer 710 is an inverted trapezoid, the second source/drain electrode layer 720 is disposed on the side of the first source/drain electrode layer 710 away from the substrate base 100, and the depositing shape of the second source/drain electrode layer is the strip structure.

In some embodiments, a planarization layer is manufactured on the second source/drain electrode layer and is provided with a through-hole on the drain electrode, an anode is manufactured on the planarization layer and is connected to the drain electrode through the through-hole. Electron/hole injection layers, a light-emitting functional layer, a cathode, and an encapsulation layer are further formed on the anode and combined together to manufacture an AMOLED light-emitting device.

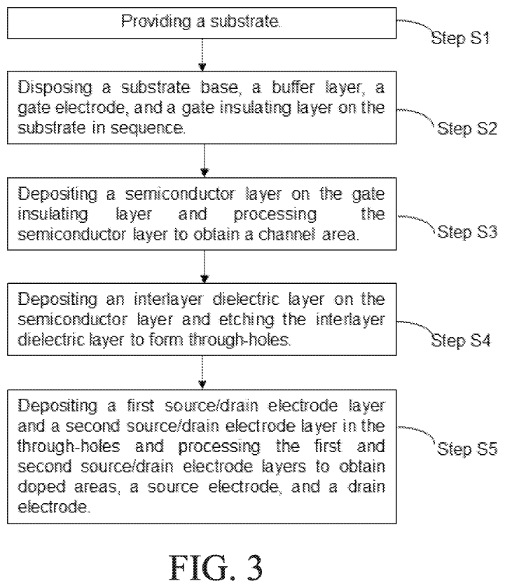

As shown in FIG. 3, the present disclosure provides a manufacturing method of the array substrate.

Step S1: providing a substrate.

Step S2: disposing the substrate base, the buffer layer, the gate electrode, and the gate insulating layer on the substrate in sequence.

Step S3: depositing a semiconductor layer on the gate insulating layer and processing the semiconductor layer to obtain the channel area.

Step S4: depositing the interlayer dielectric layer on the first semiconductor layer and etching the interlayer dielectric layer to form the through-holes.

Step S5: depositing the first source/drain electrode layer and the second source/drain electrode layer in the through-holes and processing the first and second source/drain electrode layers to obtain the doped areas, the source electrode, and the drain electrode.

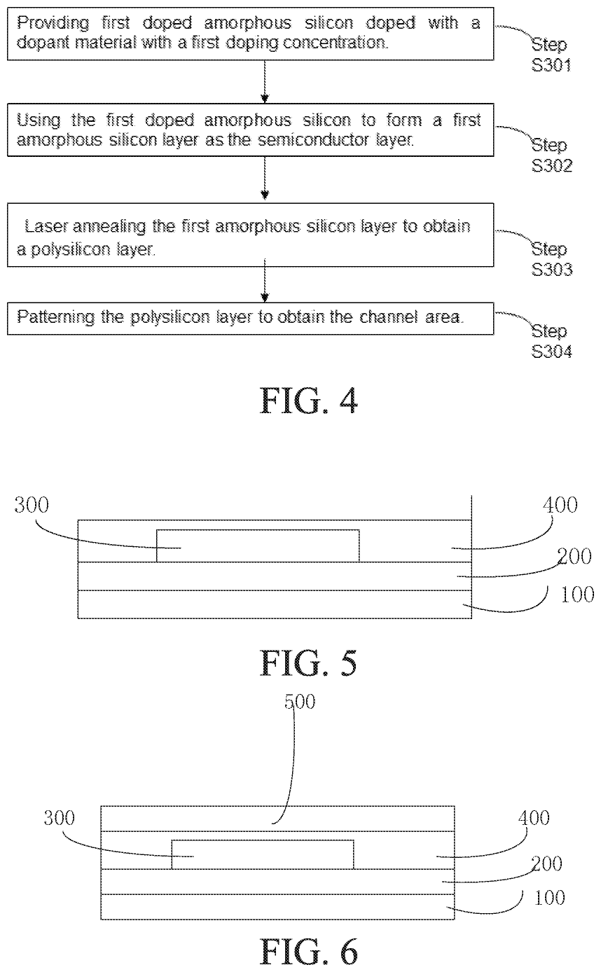

The manufacturing steps of the array substrate will be described with reference to FIGS. 4 to 9.

In the step S1, the substrate is generally a glass substrate.

As shown in FIG. 5, in the step S2, the material of the substrate base 100 is glass, a material of the buffer layer 200 includes an organic layer and an inorganic layer, the organic layer is disposed on the substrate base 100, and the inorganic layer is disposed on one side of the organic layer away from the substrate base 100. The gate electrode metal layer 300 may be manufactured by using magnetron sputtering to form a metal thin film layer on the buffer layer 200. A metal material may use molybdenum, aluminum, aluminum nickel alloy, molybdenum tungsten alloy, chrome, or copper, or combinations of thin films of the above materials. Then a gate electrode 300 is formed by exposing through a mask, developing, etching, and stripping. The gate insulating layer 400 is deposited on the gate electrode metal layer 300, and a material for the gate insulating layer 400 may be silicon nitride or silicon oxide.

As shown in FIGS. 4 and 6, the step S3 includes following steps.

Step S301: providing first doped amorphous silicon doped with a dopant material with a first doping concentration.

Step S302: using the first doped amorphous silicon to form a first amorphous silicon layer as the semiconductor layer.

Step S303: laser annealing the first amorphous silicon layer to obtain a polysilicon layer.

Step S304: patterning the polysilicon layer to obtain the channel area.

In the step S301, a reactive mixed gas is injected into the reaction chamber, under a condition of light or a high temperature, the reactive mixed gas is activated to form active ions and ion groups, and the ion groups include doping ion groups in addition to silicon ions and silicon ion groups.

In some embodiments, doping ions are P-type ions, and the mixed gas includes methane, hydrogen, and phosphorus hydride.

In some embodiments, the doping ions are B-type ions, and the mixed gas includes methane, hydrogen, and boron trifluoride.

For the step S302, the active ions and ion groups are on surfaces of the gate insulating layer and form the first doped amorphous silicon to form the first amorphous silicon layer as the semiconductor layer. The doped amorphous silicon layer has better conduction.

In the step S303, laser annealing the first amorphous silicon layer, which uses characteristics of concentrated laser energy to immediately emit high energy generated by a laser pulse onto surfaces of the amorphous silicon layer and produces a thermal effect on the surfaces of the first amorphous silicon layer within a depth of 100 nm, thereby allowing a temperature of the substrate to reach to 1000 degrees immediately with less heat generated, and allowing the first amorphous silicon layer to dissolve and crystallize again rapidly to obtain the polysilicon layer.

Step S304: patterning the polysilicon layer to obtain the channel area. The patterning process of the polysilicon layer includes coating a photoresist on a surface of the polysilicon layer, then injecting an acid etching gas into the reaction chamber, such as hydrofluoric acid, and after etching, removing the photoresist and forming the channel area of the active layer.

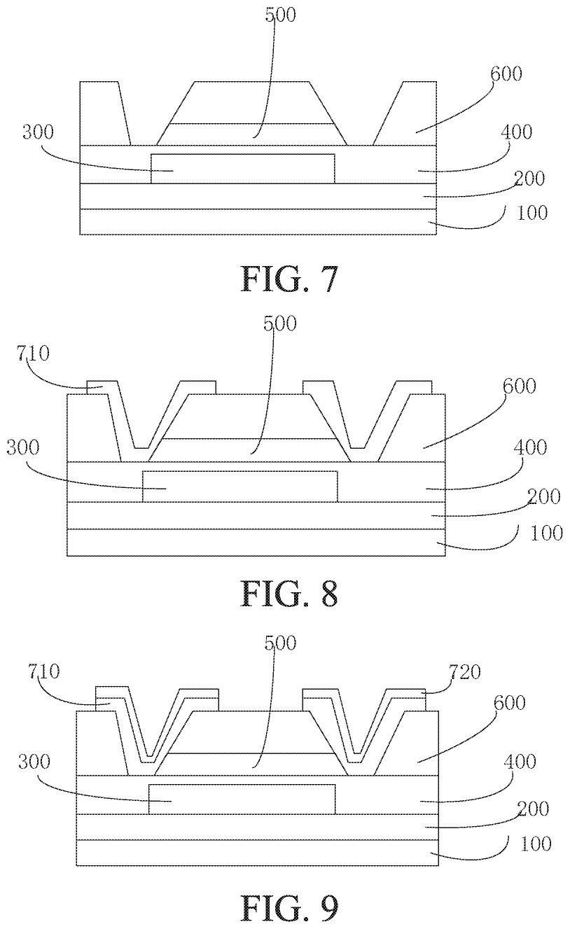

As shown in FIG. 7, in the step S4, the interlayer dielectric layer is deposited on the first semiconductor layer and is etched to form the through-holes. The material of the interlayer dielectric layer 600 is one or more of silicon oxide, silicon nitride, and phosphosilicate glass. After forming the interlayer dielectric layer 600 on the active layer 500, opening holes in the interlayer dielectric layer 600, the through-holes penetrate to the doped areas of the active layer 500 and are defined on the gate insulating layer 400, and the through-holes are defined in the doped areas of the active layer.

Step S5: depositing the first source/drain electrode layer and the second source/drain electrode layer in the through-holes and processing the first and second source/drain electrode layers to obtain the doped areas, the source electrode, and the drain electrode. As shown in FIG. 8, the material of the first source/drain electrode layer 710 is also a semiconductor layer, which has same steps as the preparation of the doped areas of the active layer 500. The mixed gas is injected into the reaction chamber to form ions and ion groups by the high temperature activation reaction. The ions and ion groups form a second amorphous silicon layer in the through-holes. Laser annealing the second amorphous silicon layer, which uses characteristics of concentrated laser energy to immediately emit high energy generated by a laser pulse onto surfaces of the amorphous silicon layer and produces a thermal effect on surfaces of the second amorphous silicon layer within a depth of 100 nm, thereby allowing a temperature of the substrate to reach to 1000 degrees immediately with less heat generated, and allowing the second amorphous silicon layer to dissolve and crystallize again rapidly to obtain a second polysilicon layer. Patterning the second polysilicon layer, the patterning process includes coating a photoresist on a surface of the polysilicon layer, then injecting an acid etching gas into the reaction chamber, such as hydrofluoric acid, and after etching, removing the photoresist and forming the first source/drain electrode layer 710. Ions doped into the first source/drain electrode layer and the active layer 500 are same, while concentrations thereof are different. As shown in FIG. 9, depositing the second source/drain electrode layer 720 on the first source/drain electrode layer by chemical vapor deposition, and the material of the second source/drain electrode layer 720 is metal titanium.

In some embodiments, the shape of the first source/drain electrode layer 710 is an inverted trapezoid, and the depositing shape of the second source/drain electrode layer is a strip structure.

In some embodiments, the shape of the first source/drain electrode layer 710 is the V-shape, and the depositing shape of the second source/drain electrode layer is also the V-shape.

In some embodiments, a planarization layer is manufactured on the second source/drain electrode layer and is provided with a through-hole on the drain electrode, an anode is manufactured on the planarization layer and is connected to the drain electrode through the through-hole. The electron/hole injection layers, a light-emitting functional layer, a cathode, and an encapsulation layer are further formed on the anode and combined together to manufacture an AMOLED light-emitting device.

In the above embodiments, the description of each embodiment has its own emphasis. For a part that is not described in detail in an embodiment, refer to the related descriptions of other embodiments.

The display panel and the manufacturing method thereof provided by the present disclosure are described in detail above. The specific examples are applied in the description to explain the principle and implementation of the disclosure. The description of the above embodiments is only for helping to understand the technical solution of the present disclosure and its core ideas, and it is understood that many changes and modifications to the described embodiment can be carried out without departing from the scope and the spirit of the disclosure that is intended to be limited only by the appended claims.

1. An array substrate, comprising:
a substrate base;
a buffer layer disposed on the substrate base;
a gate electrode metal layer disposed on one side of the buffer layer away from the substrate base;
a gate insulating layer disposed on one side of the gate electrode metal layer away from the buffer layer;
an active layer disposed on one side of the gate insulating layer away from the gate electrode metal layer and patterned to form a channel area;
an interlayer dielectric layer disposed on one side of the active layer away from the gate insulating layer; and
a source/drain electrode layer disposed on the one side of the active layer away from the gate insulating layer and patterned to form a source electrode and a drain electrode;
wherein the source/drain electrode layer comprises a first source/drain electrode layer and a second source/drain electrode layer, areas where the first source/drain electrode layer is in contact with the active layer form doped areas, the second source/drain electrode layer is disposed on one side of the first source/drain electrode layer away from the substrate base, a material of the first source/drain electrode layer is same as a material of the active layer, and ion doping concentrations of the first source/drain electrode layer and the active layer are different.

2. The array substrate according to claim 1, wherein the interlayer dielectric layer is provided with through-holes penetrating through the interlayer dielectric layer and forming flat areas on the gate insulating layer, the first source/drain electrode layer is paved over the through-holes, and the first source/drain electrode layer in the flat areas is connected to the channel area to form the doped areas.

3. The array substrate according to claim 2, wherein a shape of the through-holes comprises an inverted trapezoid.

4. The array substrate according to claim 1, wherein a thickness of the active layer is same as a thickness of the first source/drain electrode layer.

5. The array substrate according to claim 1, wherein a contact area of the second source/drain electrode layer and the first source/drain electrode layer is greater than an orthographic projection area of the second source/drain electrode layer on the substrate base.

6. A manufacturing method of an array substrate, used to manufacture the array substrate according to claim 1, comprising following steps:
providing a substrate;
disposing the substrate base, the buffer layer, a gate electrode, and the gate insulating layer on the substrate in sequence;
depositing a semiconductor layer on the gate insulating layer and processing the semiconductor layer to obtain the channel area;
depositing the interlayer dielectric layer on the semiconductor layer and etching the interlayer dielectric layer to form the through-holes; and
depositing the first source/drain electrode layer and the second source/drain electrode layer in the through-holes and processing the first and second source/drain electrode layers to obtain the doped areas, the source electrode, and the drain electrode.

7. The manufacturing method according to claim 6, wherein the step of depositing the semiconductor layer on the gate insulating layer and processing the semiconductor layer to obtain the channel area comprises:
providing first doped amorphous silicon doped with a dopant material with a first doping concentration;
using the first doped amorphous silicon to form a first amorphous silicon layer as the semiconductor layer;
laser annealing the first amorphous silicon layer to obtain a polysilicon layer; and
patterning the polysilicon layer to obtain the channel area.

8. The manufacturing method according to claim 7, wherein the step of providing the first doped amorphous silicon doped with the dopant material with the first doping concentration comprises:
injecting methane, hydrogen, and phosphorus hydride into a reaction chamber and dissociating them under a thermal energy condition or a light energy condition to obtain the first doped amorphous silicon.

9. The manufacturing method according to claim 7, wherein the step of providing the first doped amorphous silicon doped with the dopant material with the first doping concentration comprises:
injecting methane, hydrogen, and boron trifluoride into a reaction chamber and dissociating them under a thermal energy condition or a light energy condition to obtain the first doped amorphous silicon.

10. The manufacturing method according to claim 6, wherein the step of depositing the first source/drain electrode layer and the second source/drain electrode layer in the through-holes and processing the first and second source/drain electrode layers to obtain the doped areas, the source electrode, and the drain electrode comprises:
providing second doped amorphous silicon doped with a dopant material with a second doping concentration;
using the second doped amorphous silicon to form a second amorphous silicon layer to be the first source/drain electrode layer;
disposing the second source/drain electrode layer on the second amorphous silicon layer; and
patterning the second doped amorphous silicon and the second source/drain electrode layer to obtain the doped areas, the source electrode, and the drain electrode.

11. A display panel comprising an array substrate, wherein the array substrate comprises:
a substrate base;
a buffer layer disposed on the substrate base;
a gate electrode metal layer disposed on one side of the buffer layer away from the substrate base;
a gate insulating layer disposed on one side of the gate electrode metal layer away from the buffer layer;
an active layer disposed on one side of the gate insulating layer away from the gate electrode metal layer and patterned to form a channel area;
an interlayer dielectric layer disposed on one side of the active layer away from the gate insulating layer; and
a source/drain electrode layer disposed on the one side of the active layer away from the gate insulating layer and patterned to form a source electrode and a drain electrode;
wherein the source/drain electrode layer comprises a first source/drain electrode layer and a second source/drain electrode layer, areas where the first source/drain electrode layer is in contact with the active layer form doped areas, the second source/drain electrode layer is disposed on one side of the first source/drain electrode layer away from the substrate base, a material of the first source/drain electrode layer is same as a material of the active layer, and ion doping concentrations of the first source/drain electrode layer and the active layer are different.

12. The display panel according to claim 11, wherein the interlayer dielectric layer is provided with through-holes penetrating through the interlayer dielectric layer and forming flat areas on the gate insulating layer, the first source/drain electrode layer is paved over the through-holes, and the first source/drain electrode layer in the flat areas is connected to the channel area to form the doped areas.

13. The display panel according to claim 12, wherein a shape of the through-holes comprises an inverted trapezoid.

14. The display panel according to claim 11, wherein a thickness of the active layer is same as a thickness of the first source/drain electrode layer.

15. The display panel according to claim 11, wherein a contact area of the second source/drain electrode layer and the first source/drain electrode layer is greater than an orthographic projection area of the second source/drain electrode layer on the substrate base.

16. A manufacturing method of a display panel, used to manufacture the display panel according to claim 11, comprising following steps:
providing a substrate;
disposing the substrate base, the buffer layer, a gate electrode, and the gate insulating layer on the substrate in sequence;
depositing a semiconductor layer on the gate insulating layer and processing the semiconductor layer to obtain the channel area;
depositing the interlayer dielectric layer on the semiconductor layer and etching the interlayer dielectric layer to form the through-holes; and
depositing the first source/drain electrode layer and the second source/drain electrode layer in the through-holes and processing the first and second source/drain electrode layers to obtain the doped areas, the source electrode, and the drain electrode.

17. The manufacturing method according to claim 16, wherein the step of depositing the semiconductor layer on the gate insulating layer and processing the semiconductor layer to obtain the channel area comprises:
providing first doped amorphous silicon doped with a dopant material with a first doping concentration;
using the first doped amorphous silicon to form a first amorphous silicon layer as the semiconductor layer;
laser annealing the first amorphous silicon layer to obtain a polysilicon layer; and
patterning the polysilicon layer to obtain the channel area.

18. The manufacturing method according to claim 17, wherein the step of providing the first doped amorphous silicon doped with the dopant material with the first doping concentration comprises:
injecting methane, hydrogen, and phosphorus hydride into a reaction chamber and dissociating them under a thermal energy condition or a light energy condition to obtain the first doped amorphous silicon.

19. The manufacturing method according to claim 17, wherein the step of providing the first doped amorphous silicon doped with the dopant material with the first doping concentration comprises:
injecting methane, hydrogen, and boron trifluoride into a reaction chamber and dissociating them under a thermal energy condition or a light energy condition to obtain the first doped amorphous silicon.

20. The manufacturing method according to claim 16, wherein the step of depositing the first source/drain electrode layer and the second source/drain electrode layer in the through-holes and processing the first and second source/drain electrode layers to obtain the doped areas, the source electrode, and the drain electrode comprises:
providing second doped amorphous silicon doped with a dopant material with a second doping concentration;
using the second doped amorphous silicon to form a second amorphous silicon layer to be the first source/drain electrode layer;
disposing the second source/drain electrode layer on the second amorphous silicon layer; and
patterning the second doped amorphous silicon and the second source/drain electrode layer to obtain the doped areas, the source electrode, and the drain electrode.
